(19) United States
(12) Patent Application Publication
(10) Pub. No.: US 2026/0011681 A1
(43) Pub. Date: Jan. 8, 2026

(54) HOLDING HEAD STRUCTURE AND MANUFACTURING METHOD OF SEMICONDUCTOR STRUCTURE USING THE SAME

(71) Applicant: Taiwan Semiconductor Manufacturing Company, Ltd., Hsinchu (TW)

(72) Inventors: Wen-Yun Wang, Taipei City (TW); Chao-Wen Shih, Hsinchu County (TW); Kuo-Chiang Ting, Hsinchu City (TW); Yen-Ming Chen, Hsin-Chu County (TW)

(73) Assignee: Taiwan Semiconductor Manufacturing Company, Ltd., Hsinchu (TW)

(21) Appl. No.: 18/764,189

(22) Filed: Jul. 4, 2024

(51) Int. Cl. H01L 23/00

(52) U.S. Cl. CPC H01L 24/80; H01L 24/74; H01L 2224/74; H01L 2224/80203; H01L 2224/80895; H01L 2224/80896; H01L 2924/40

(57) ABSTRACT

A holding head structure and a manufacturing method using the same are disclosed. The holding head structure includes a body of a matrix material, a plurality of operating cores embedded in the matrix material of the body, and a plurality of isolators in the body and defining holding units. The holding units are electrically isolated from one another by the plurality of isolators. Each holding unit includes at least one operating core, and each holding unit is configured to be individually controlled and be electrically connected to a power source.

### BACKGROUND

Semiconductor wafers are fabricated with devices, electronic components and integrated circuits. The wafers and the dies fabricated from the wafers may be processed, bonded and packaged with other semiconductor wafers, dies or components at the wafer level, and various technologies have been developed for the wafer level packaging.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 8 are schematic cross-sectional views showing various stages in a manufacturing method of a semiconductor stacked structure in accordance with some embodiments of the disclosure.

FIG. 2′ is a schematic cross-sectional view showing an exemplary structure of a semiconductor structure in accordance with some embodiments of the disclosure.

FIG. 9 is a schematic three-dimensional view illustrating an exemplary structure of a holding head structure.

FIG. 10 is a schematic bottom view illustrating a plurality of holding units within the holding head structure in accordance with some embodiments of the disclosure.

FIGS. 11-12 are schematic top views illustrating relative positions between the holding head structure and one or more semiconductor structures in accordance with some embodiments of the disclosure.

FIG. 13 is a schematic cross-sectional view illustrating a processing system for the manufacturing of a semiconductor stacked structure according to some exemplary embodiments of the present disclosure.

FIGS. 14-16 are schematic cross-sectional views showing various stages in a manufacturing method of a semiconductor stacked structure in accordance with some embodiments of the disclosure.

FIGS. 17-18 are schematic process flow showing the process steps of manufacturing methods of semiconductor stacked structures in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth” and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

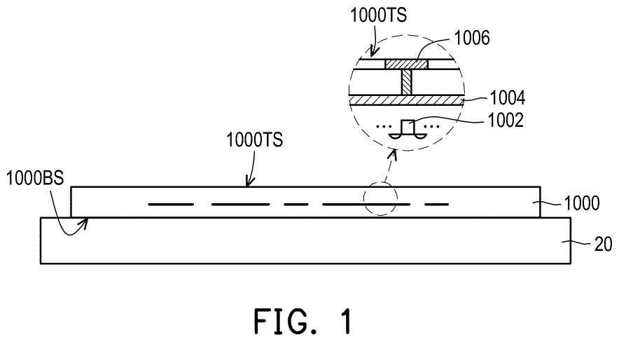

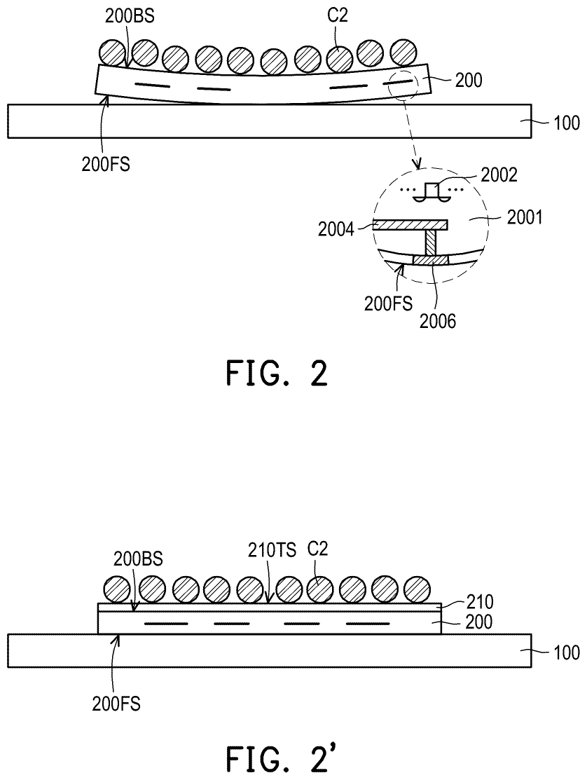

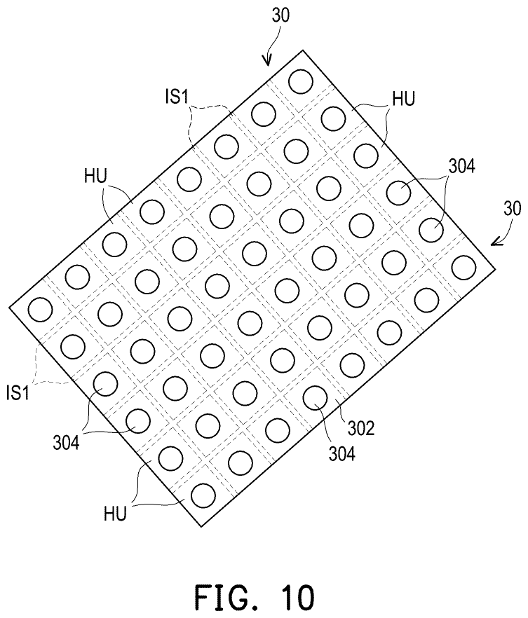

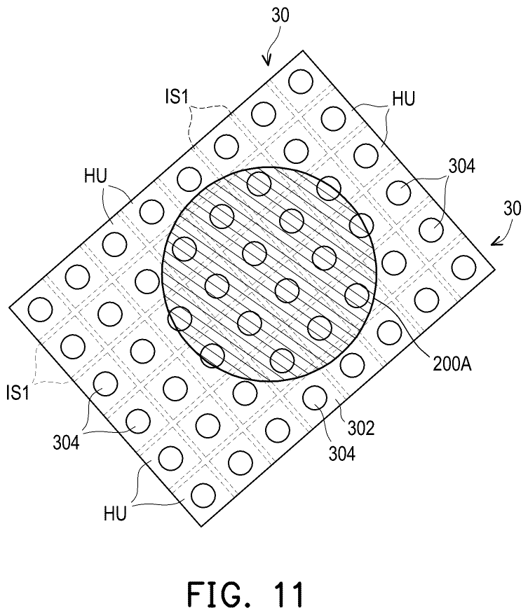

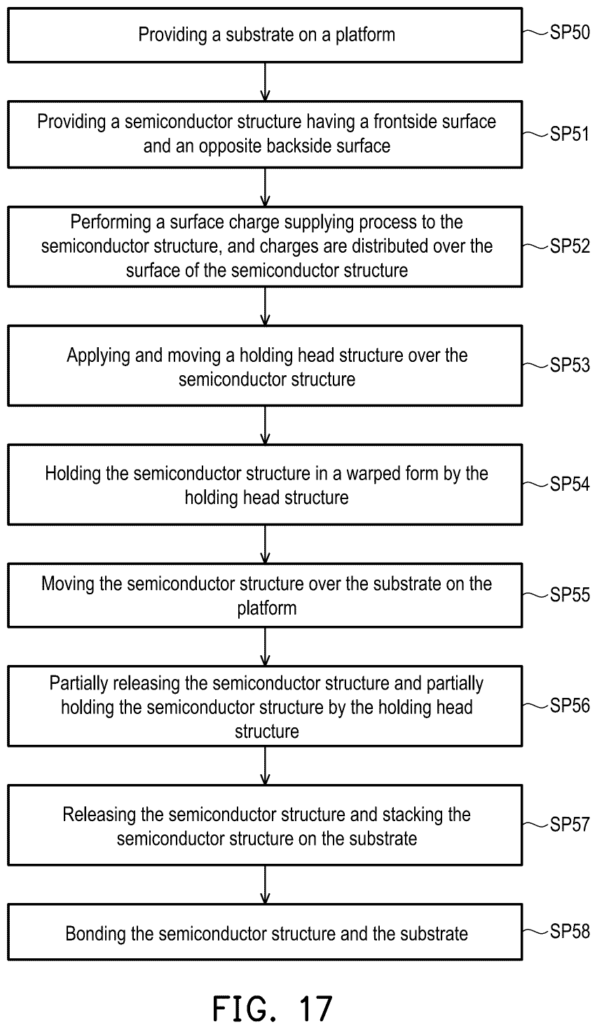

FIG. 1 through FIG. 8 are schematic cross-sectional views showing various stages in a manufacturing method of a semiconductor stacked structure in accordance with some embodiments of the disclosure. FIG. 9 is a schematic three-dimensional view illustrating an exemplary structure of a holding head structure. FIG. 10 is a schematic bottom view illustrating a plurality of holding units within the holding head structure in accordance with some embodiments of the disclosure. In some embodiments, the manufacturing method is part of a semiconductor packaging process. From FIG. 2 to FIG. 8, although one semiconductor structure is shown as an example, it is understood that more than one semiconductor structures may be bonded onto the substrate(s), and the semiconductor structures may include semiconductor wafers, reconstructed wafers, chips/dies, electronic components or package subunits, and one semiconductor bonded stacked structure is shown to represent plural semiconductor bonded structures obtained following the semiconductor manufacturing method, however the disclosure is not limited thereto. FIG. 17 is a schematic process flow showing the process steps of a manufacturing method of a semiconductor stacked structure in accordance with some embodiments of the disclosure.

Referring to FIG. 1 and referring to process step SP50, in some embodiments, a substrate 1000 is provided and disposed on a platform 20. In some embodiments, the platform 20 is located within and as a part of a processing chamber for performing one or more processes during semiconductor manufacturing. In some embodiments, the substrate 1000 includes a semiconductor substrate, and the semiconductor substrate includes a bulk semiconductor substrate, a semiconductor-on-insulator (SOI) substrate, other supporting substrate (e.g., quartz, glass, etc.), combinations thereof, or the like. In some embodiments, the substrate 1000 is a semiconductor wafer including an elementary semiconductor (e.g., silicon or germanium), a compound semiconductor (e.g., silicon carbide, gallium arsenide, gallium phosphide, indium phosphide, indium arsenide, and/or indium antimonide, etc.), an alloy semiconductor (e.g., silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc.), or combinations thereof. The substrate 1000 may have a multilayer structure, including more than one types of semiconductor materials.

In some embodiments, the substrate 1000 is a wafer including a plurality of integrated circuit components (not shown) arranged in an array and connected to one another before performing a wafer sawing or dicing process. For example, as seen in the schematic partially enlarged view of FIG. 1, the substrate 1000 includes semiconductor devices 1002 formed therein, interconnect structures 1004 electrically connected with some of the semiconductor devices 1002, and bonding structures 1006 formed on the interconnect structures 1004. In some embodiments, the bonding structures 1006 may include metallic bonding pads embedded in the dielectric bonding film(s). For example, the substrate 1000 may include circuitry formed from semiconductor devices 1002 formed through front-end-of-line (FEOL) processes, and the interconnect structures 1004 and bonding structures 1006 may be formed through middle-end-of-line (MEOL) and back-end-of-line (BEOL) processes. In some embodiments, the bonding structures 1006 are electrically connected with the semiconductor devices 1002 through the interconnect structures 1004.

In some embodiments, the semiconductor devices 1002 include active devices (e.g., transistors, diodes, etc.), and optionally passive devices (e.g., capacitors, resistors, inductors, etc.), and/or other suitable electrical components. In some embodiments, as shown in FIG. 1, the substrate 1000 has a top surface 1000TS and a bottom surface 1000BS opposite to the top surface 1000TS. For example, the substrate 1000 is provided with the top surface 1000TS being a bonding surface with the bonding structures 1006 on the top surface 1000TS for assisting later bonding.

Referring to FIG. 2 and referring to process step SP51, a semiconductor structure 200 is provided on a carrier 100. In some embodiments, the carrier 100 is a temporary carrier, including a plastic supporting board, a polymeric tape, a glass plate, a metal plate, or any other suitable supportive materials may be used as long as the materials are able to withstand the subsequent steps of the process. When the semiconductor structure 200 is disposed on the temporary carrier 100 with the frontside surface 200FS facing the carrier 100 and the opposite backside surface 200BS of the semiconductor structure 200 is exposed and available for further processing.

In some embodiments, the semiconductor structure 200 is or includes a semiconductor wafer. In some embodiments, the semiconductor wafer is a silicon bulk wafer. In some embodiments, the semiconductor wafer may be a silicon-on-insulator (SOI) wafer, a germanium-on-insulator (GOI) or a wafer comprising elementary semiconductor materials such as silicon or germanium. In some embodiments, the semiconductor structure 200 is a semiconductor die or includes at least one or several semiconductor dies formed from wafer dicing or singulation of a semiconductor wafer or a reconstructed wafer. The semiconductor structure 200 may have a multilayer structure, including different types of semiconductor materials and dielectric materials along with conductors. The semiconductor structure 200 may be provided in various shapes, including wafers of round or circular shapes, reconstructed wafers or diced structures or dies of round, tetragonal or polygonal shapes. As seen in FIG. 2, in some embodiments, when the sizes (such as the diameter for round or oval shapes) of the semiconductor structure 200 are relatively large, the semiconductor structure 200 may be slightly warped or twisted (i.e. non-linear shaped from cross-sectional view).

In some embodiments, the semiconductor structure 200 includes a semiconductor substrate 2001, semiconductor devices 2002 formed therein, interconnect structures 2004 electrically connected with some of the semiconductor devices 2002, and bonding structures 2006 formed on the interconnect structures 2004. In some embodiments, the bonding structures 2006 may include metallic bonding pads embedded in the dielectric bonding film(s). For example, the semiconductor structure 200 includes circuitry composed of semiconductor devices 2002 formed through FEOL processes, and the interconnect structures 2004 and bonding structures 2006 formed through MEOL and BEOL processes.

In some embodiments, the semiconductor devices 2002 may include active devices (e.g., transistors, diodes, etc.), and optionally passive devices (e.g., capacitors, resistors, inductors, etc.), or other suitable electrical components such as micro-electro-mechanical structural (MEMS) components or optoelectronic components. In some embodiments, the bonding structures are electrically connected with the semiconductor devices 2002 formed in the semiconductor substrate 2001 through the interconnect structures 2004. In some embodiments, as shown in the schematic partially enlarged view of FIG. 2, the bonding structures 2006 are disposed on the frontside surface 200FS (as the bonding surface) of the semiconductor structure 200.

Referring to FIG. 2 and referring to process step SP52, in some embodiments, a surface charge supplying process is performed to make the backside surface 200BS of the semiconductor structure 200 electrostatically charged, and the charges C2 may be distributed mostly uniformly over the backside surface 200BS. In some embodiments, backside surface 200BS of the semiconductor structure 200 is electro-positively charged, and the charges C2 include positive charges. In some embodiments, backside surface 200BS of the semiconductor structure 200 is electro-negatively charged, and the charges C2 include negative charges. In some embodiments, the surface charge supplying process performed to the backside surface 200BS of the semiconductor structure 200 includes performing a plasma treatment, an ion implantation process, a surface treatment using an electron emitter (electron gun), or a spraying process using an electroconductive electrolyte or ionic solution. By tuning the conditions and parameters of the surface charge supplying process, the charges C2 can be set to be positive charges or negative charges, and the charge density of the charges C2 over the backside surface 200BS can be set to be a predetermined value (a fixed value). In one embodiment, after performing the surface charge supplying process, the backside surface 200BS of the semiconductor structure 200 is electronegatively charged and the charges C2 are negative charges distributed uniformly over the whole backside surface 200BS.

In other embodiments, referring to FIG. 2′, a semiconductor structure 200 is provided with a chargeable film 210 formed thereon, and the stack structure of the semiconductor structure 200 and the chargeable film 210 is disposed on the carrier 100. Herein, the elements similar to or substantially the same as the elements described above will use the same reference numbers, and certain details or descriptions of the same elements (e.g. the materials) and the relationship thereof (e.g. the relative positioning configuration and electrical connection) will not be repeated herein. When the stack structure of the semiconductor structure 200 and the chargeable film 210 is disposed on the temporary carrier 100 with the frontside surface 200FS facing the carrier 100 and the opposite backside surface 200BS of the semiconductor structure 200 is covered by the chargeable film 210 and the top surface 210TS is exposed and available for further processing. As seen in FIG. 2′, in some embodiments, the semiconductor structure 200 is substantially planar or flat relative to the surface of the carrier 100. Later, the surface charge supplying process is performed to make the top surface 210TS of the chargeable film 210 electrostatically charged, and the charges C2 may be distributed mostly uniformly over the top surface 210TS of the chargeable film 210.

In some embodiments, the chargeable film 210 includes a dielectric material. In some embodiments, the dielectric material of the chargeable film 210 is or includes silicon nitride, silicon oxide, silicon carbonitride, carbon nitride, or a combination thereof. In some embodiments, the chargeable film 210 may be formed by chemical vapor deposition (CVD), such as thermal CVD, atmospheric pressure CVD, low pressure CVD, or plasma-enhanced CVD. Similarly, the charges C2 may be negative or positive, depending on what kind of surface charge supplying process is performed. In some embodiments, the charges C2 distributed uniformly over the top surface 210TS of the chargeable film 210 are negative. Herein, without directly treating or charging the semiconductor structure 200, the additionally formed chargeable film 210 is treated to carry the charges C2. In some embodiments, the material of the chargeable film 210 is chosen to protect the semiconductor structure 200, being easily removed in subsequent process, and to be easily charged for assisting holding and carrying.

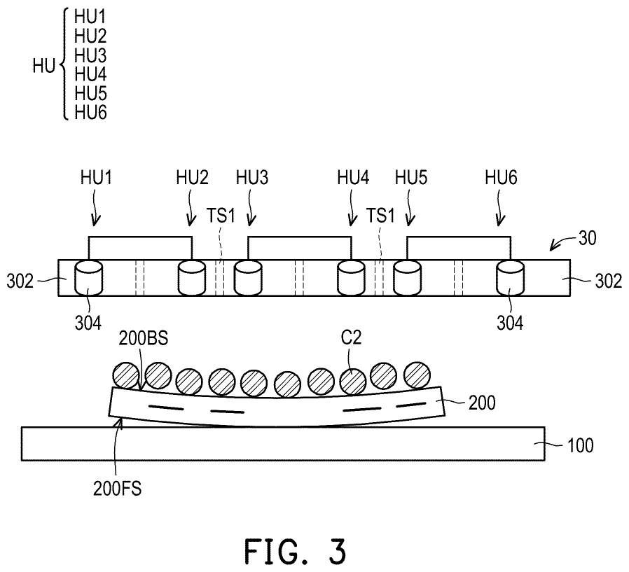

Referring to FIG. 3 and referring to process step SP53, after providing the substrate 1000 and providing the semiconductor structure 200, a holding head structure 30 is applied, moving to a position above the semiconductor structure 200, and is then placed over the semiconductor structure 200 with the backside surface 200BS facing the holding head structure 30. In some embodiments, the holding head structure 30 includes a plurality of holding units HU including holding units HU1-HU6. As seen in FIG. 3, for the illustration purposes, only a portion of the holding head structure 30 is shown with the six holding units HU1-HU6. It is understood that six holding units are shown in FIG. 3 as representatives, and the number of the holding units is at least three or more, and may be adjusted based on the design of the holding head structure 30. In some embodiments, the holding head structure 30 may function as a bond head for assisting precise alignment and stacking of semiconductor structures and/or further assisting the bonding of the stacked structures.

Referring to FIG. 9 and FIG. 10, in some embodiments, the holding head structure 30 includes a body 302 made of a matrix material and a plurality of operating cores 304 embedded in the matrix material of the body 302. In some embodiments, the holding head structure 30 includes a plurality of holding units HU defined by isolators IS1 (shown as dotted lines) and the holding units HU are isolated from one another by the isolators IS1, and each holding unit HU includes at least one operating core 304 embedded or inlaid in the body 302. In certain embodiments, each operating core 304 that is electrically connected to a power source through the connected wire 305 is individually controlled. In some embodiments, each holding unit HU is electrically isolated from one another by the isolators IS1 located therebetween. In some embodiments, the matrix material of the body 302 includes an insulative dielectric material, a ceramic material or mixtures thereof, and the material of the isolators IS1.

In some embodiments, the operating core 304 is or includes at least one electrode. In some embodiments, the operating core is or includes at least one electromagnet. For each holding unit, the number of the electrodes or the electromagnets in the operating core 304 may be adjusted based on the designs. During operation, the individual operating core 304 is independently controlled through the controller or a controlling unit. For example, each of the operating cores 304 includes an electrode, and each holding unit HU is independently controlled to be electro-negatively charged or electro-positively charged by applying negative voltage or positive voltage. For instance, each of the operating cores 304 includes an electromagnet, and each holding unit HU is independently controlled to tune the strength of the magnetic field.

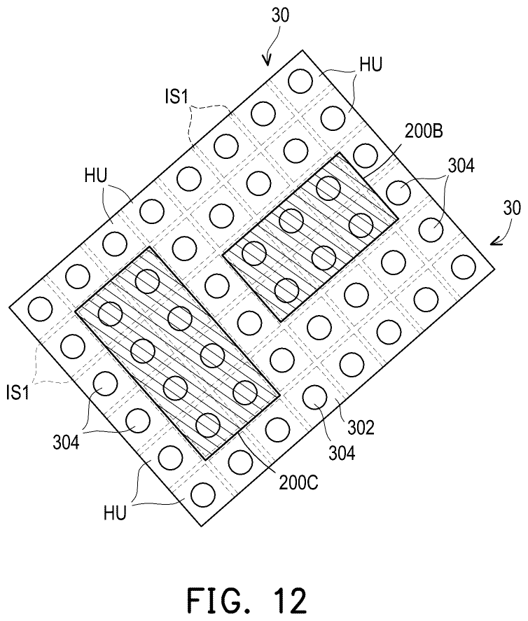

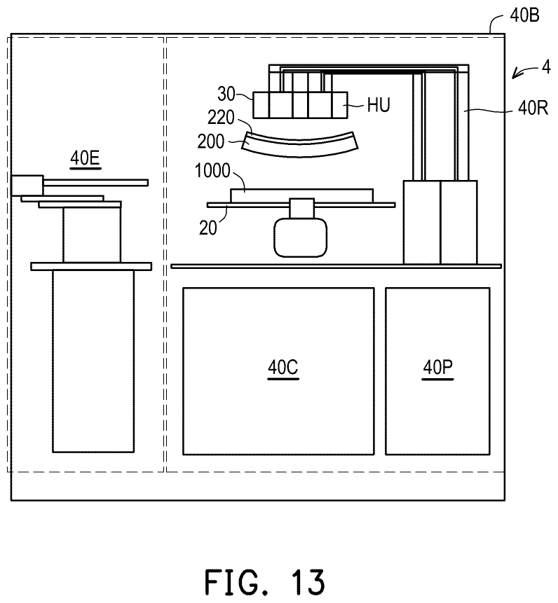

FIGS. 11-12 are schematic top views illustrating relative positions between the holding head structure and one or more semiconductor structures in accordance with some embodiments of the disclosure. In some embodiments, if the semiconductor structure 200A is a semiconductor wafer in a round shape, it is seen that the semiconductor structure 200A is held or carried by the holding head structure 30 when the holding head structure 30 is operated (some or all of the holding units HU are in operation). Referring to FIG. 11, it is seen that the span or size of the holding head structure 30 is larger than the span of the semiconductor structure 200A, and some of the holding units HU located within the span of the semiconductor structure 200A may be operated for holding/releasing. Referring to FIG. 12, in some embodiments, two semiconductor structures 200B and 200C are semiconductor dies in different sizes, and both semiconductor structures 200B and 200C are held or carried by the holding head structure 30 when the holding head structure 30 is operated (some or all of the holding units HU are in operation). Referring to FIG. 12, the span of the holding head structure 30 is larger than the span of the semiconductor structure 200B or 200C, and the holding units HU located within the span of the semiconductor structure 200B or within the span of the semiconductor structure 200C may be operated for holding/releasing.

As the holding head structure 30 is designed to include a plurality of holding units over a relatively large span (larger than the to-be-carried objects), it is flexible to hold or carry objects of different sizes or shapes, and/or multiple objects at the same time.

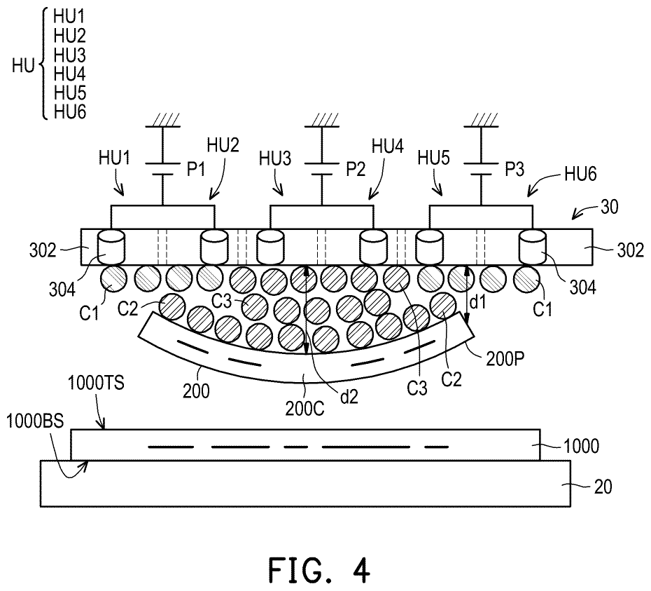

Referring back to FIG. 4, following the process of FIG. 3, the holding head structure 30 is operated, and the holding units HU1-HU6 are in operation. During operation, some of the holding units may be working in pairs or in groups and are electrically connected in series or in parallel depending on the desirable working status. For example, the holding units HU1 and HU2 are electrically connected in parallel and connected to a first power source P1, the holding units HU3 and HU4 are electrically connected in parallel and connected to a second power source P2, and the holding units HU5 and HU6 are electrically connected in parallel and connected to a third power source P3. In some embodiments, during operation, for the exemplary holding head structure 30 having each of the operating cores 304 including an electrode, each of the holding units HU1-HU6 of the holding head structure 30 is independently controlled to be electro-negatively charged or electro-positively charged by applying negative voltage or positive voltage.

For the holding head structure 30, by adjusting the voltages through different power sources respectively connected to the corresponding holding units, the holding units HU1 and HU2 are electro-positively charged with a voltage V1 and positive charges C1 are distributed over the bottom surfaces 30BS of the holding units HU1 and HU2, and the holding units HU5 and HU6 are electro-positively charged with a voltage V2 and positive charges C1 are distributed over the bottom surfaces 30BS of the holding units HU5 and HU6. In some embodiments, the holding units HU3 and HU4 are electro-negatively charged with a voltage V3 and negative charges C3 are distributed over the bottom surfaces 30BS of the holding units HU3 and HU4. In some embodiments, more negative charges C3 existing over the bottom surfaces 30BS of the holding units HU3 and HU4, when compared with the positive charges C1 distributed over the bottom surfaces 30BS of the holding units HU5 and HU6 or of the holding units HU1 and HU2. That is, the charge density (as represented by more amounts of negative charges C3) of the holding units HU3 and HU4 is higher than the charge density (as represented by less amount of positive charges C1) of the holding units HU5 and HU6 or of the holding units HU1 and HU2.

Referring to FIG. 4 and referring to process step SP54, the holding head structure 30 is in operation and approaches the semiconductor structure 200 until it is in proximate with the semiconductor structure 200. When the holding head structure 30 is brought close to the semiconductor structure 200, but not in touch with the semiconductor structure 200, the semiconductor structure 200 is held by the holding head structure 30 through the electrostatic reaction. In some embodiments, as seen in FIG. 4, with the negative charges C2 distributed over the backside surface 200BS of the semiconductor structure 200, the peripheral portion(s) 200P of the semiconductor structure 200 is attached to and held toward the holding units HU5 and HU6 as well as the holding units HU1 and HU2 through the attraction between the negative charges C2 and the positive charges C1. Also, in some embodiments, the central portion(s) 200C of the semiconductor structure 200 is driven away from the holding units HU3 and HU4 due to the repulsion between the negative charges C2 and the negative charges C3. As seen in FIG. 4 and referring to process step SP54, in some embodiments, the semiconductor structure 200 becomes deformed and warped into a smile shape (from the cross-sectional view). In some embodiments, the semiconductor structure 200 is deformed with the peripheral portion(s) 200P being closely held (i.e. attached without being in contact with) to the holding units HU5 and HU6 as well as the holding units HU1 and HU2 with a distance d1, and the central portion 200C being more distantly held to the holding units HU3 and HU4 with a distance d2 that is larger than the distance d1. In some embodiments, the peripheral portion 200P may be ring-shaped surrounding the central portion 200C. In some embodiments, the central portion 200C (the span corresponding to the spans of the holding units HU3 and HU4) is sandwiched between the peripheral portions 200P (their spans corresponding to the spans of the holding units HU1, HU2, HU5 and HU6). In some embodiments, the semiconductor structure 200 is deformed as a crying shape, a wavy shape or any curvy shape from the cross-sectional view, as different portions of the semiconductor structure 200 may be held by various holding units of the holding head structure with different spaced apart distances. As seen in FIG. 4, through the electrostatic reaction, the semiconductor structure 200 is still spaced apart from (without physically contacting) the holding head structure 30 but is firmly carried by the holding head structure 30. Later, referring to FIG. 4 and referring to process step SP55, the semiconductor structure 200 is carried by the holding head structure 30 in a warped form, and is moved to a position above and over the substrate 1000 on the platform 20.

Through the individually controlled holding units HU of the holding head structure 30, different conductive types of charges (either positive or negative) can be applied to individual or corresponding holding units, and variable amounts of charges (i.e. various charge densities) can be applied to different holding units.

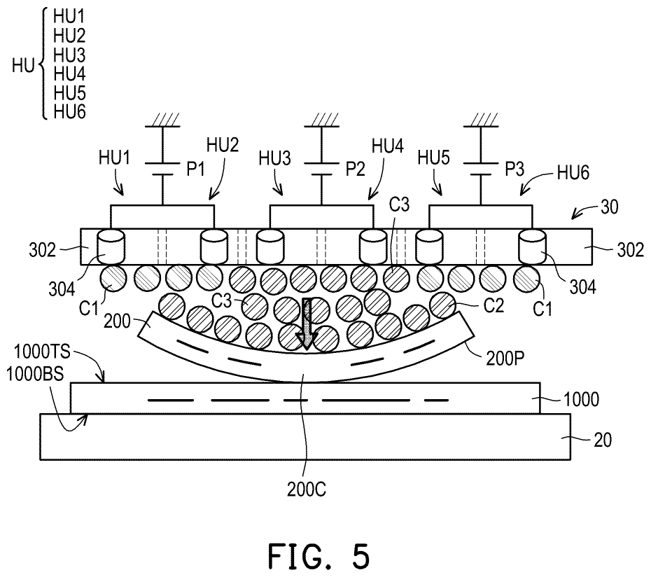

Referring to FIG. 5 and referring to process step SP56, in some embodiments, the semiconductor structure 200 carried by the holding head structure 30 in a warped form and is moved downward until the central portion 200C is in contact with the substrate 1000 on the platform 20. As the semiconductor structure 200 is deformed and the central portion 200C is more distantly held to (e.g. repulsed from) the holding units HU3 and HU4 with a larger distance d2, the central portion 200C reaches the substrate 1000 earlier than the peripheral portion(s) 200P. Also, the charge repulsion between the central portion 200C and the holding units HU3 and HU4 may exert a downward force (represented by the arrow) to join and fix the central portion 200C to the substrate 1000. In some embodiments, the downward force may be proportionally tuned by tuning the charge density of the holding units.

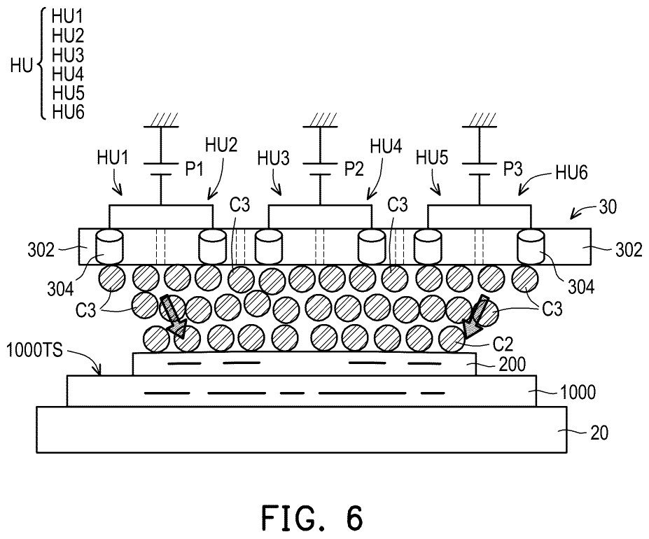

Referring to FIG. 6 and referring to process steps SP56 & SP57, following the stacking of the central portion 200C onto the substrate 1000, through the controlling unit, the holding units HU2 and HU4 as well as the holding units HU1 and HU2 are switched to have negative charges C3 distributed over their bottom surfaces, so that the peripheral portion(s) 200P is also repulsed from the holding units HU5 and HU6 as well as the holding units HU1 and HU2 toward the substrate 1000. Similarly, the charge repulsion between the peripheral portion(s) 200P and the holding units HU1, HU2, HU5 and HU6 may exert downward forces (represented by the arrows) to join and fix the peripheral portion(s) 200P to the substrate 1000. That is, the peripheral portion(s) 200P is no longer held by the holding units HU1, HU2, HU5 and HU6 and is stacked onto the substrate 1000.

Following the processes SP54-57 performed in sequence, the central portion 200C of the carried semiconductor structure 200 is firstly placed and joined with the substrate 1000, while the peripheral portion(s) 200P is placed later and joined with the substrate 1000. By doing so, stacking issues like bulges or air gaps can be avoided, and optimal stacking between the semiconductor structure and the substrate is achieved with a larger process window and high yields.

By controlled the holding units HU of the holding head structure 30 to have different types of charges and different charge densities at the same time, the shape of the carried semiconductor structure may be tuned and deformed in a way in response with the corresponding locations of the to-be landed substrate. Further, by switching the types of charges for the individual holding units at different time sequences to cause attraction or repulsion, the object structure is to be held or released.

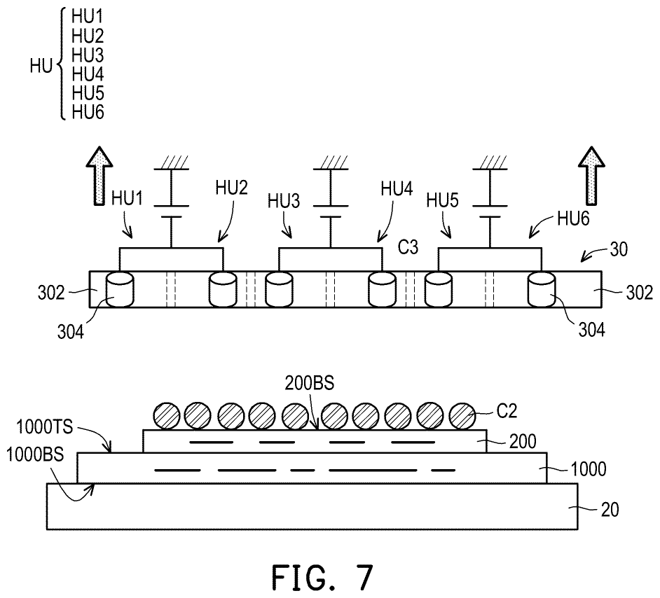

Referring to FIG. 7, the holding head structure 30 is turned off (not in operation) and then moving away from the substrate 1000, the semiconductor structure 200, including the peripheral portion(s) 200P and the central portion 200C, is released from the holding head structure 30, and is stacked onto the top surface 1000TS of the substrate 1000. In some embodiments, some charges C2 remains on the backside surface 200BS of the semiconductor structure 200. In some embodiments, a de-charging process is performed to remove the charges C2 remained on the backside surface 200BS of the semiconductor structure 200. For example, the de-charging process includes blowing ionized wind using the ionized fan or performing a rinsing process using an electrolyte or ionic solution.

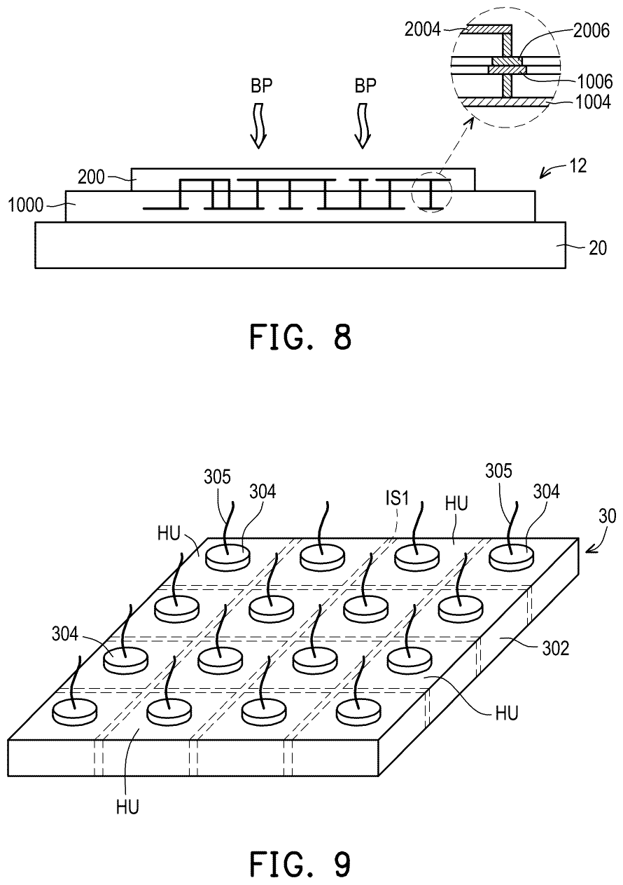

Referring to FIG. 8 and referring to process step SP58, in some embodiments, the semiconductor structure 200 (including the peripheral portion(s) 200P and the central portion 200C) and the substrate 1000 are bonded. For example, the frontside surface 200FS of the semiconductor structure 200 and the top surface 1000TS prop against each other and are bonded together through fusion bonding, dielectric-to-dielectric bonding, metallic bonding, combinations thereof or other bonding techniques. In some embodiments, a bonding process BP is performed, and the bonding process BP involves performing one or more thermal processes under a suitable working pressure.

As seen in the partially enlarged view of FIG. 8, through the bonding structures 2006 and 1006, and the semiconductor structure 200 is electrically connected with the substrate 1000 through the bonded bonding structure 2006, 1006 and the interconnect structures 2004, 1004. For example, the bonding process includes performing a heating and pressurizing process at a temperature of about 150 degrees Celsius to about 250 degrees Celsius to bond the bonding structures 2006, 1006 through dielectric-to-dielectric bonding from the bonding films and metallic-to-metallic bonding from the bonding pads (i.e. a hybrid bonding interface between the bonded bonding structures 1006 and 2006). In some embodiments, the semiconductor structure 200 is bonded to the substrate 1000 to form a bonded stacked structure 12. In one embodiment, the bonded stacked structure 12 is or includes a wafer-stacked-on wafer structure. In one embodiment, the bonded stacked structure 12 is or includes a die-stacked-on-wafer structure. However, the disclosure is not specifically limited thereto.

FIG. 13 is a schematic cross-sectional view illustrating a processing system for the manufacturing of a semiconductor stacked structure according to some exemplary embodiments of the present disclosure. In some embodiments, referring to FIG. 13, within the processing system 4, in addition to the front-end module 40E responsible for the batch supply of wafers and carriers, the processing chamber 40B includes holding head structure 30 located within the chamber 40B, robot arm module 40R connected with the holding head structure 30 for transferring and moving the holding head structure 30, power supply unit 40P including various power sources, and controlling unit 40C responsible for controlling the holding head structure 30 and other modules. Referring to FIG. 13, the substrate 1000 is placed on the platform 20 in the chamber 40B, and the semiconductor structure 200D is held by the holding head structure 30. In some embodiments, the holding head structure 30 further including sensing and alignment unit (not shown) in order to control the precise alignment of the held object relative to the location of the underlying substrate. In some embodiments, the processing chamber 40B includes a hotplate pressor or a bonding unit (not shown) for bonding the stacked structures.

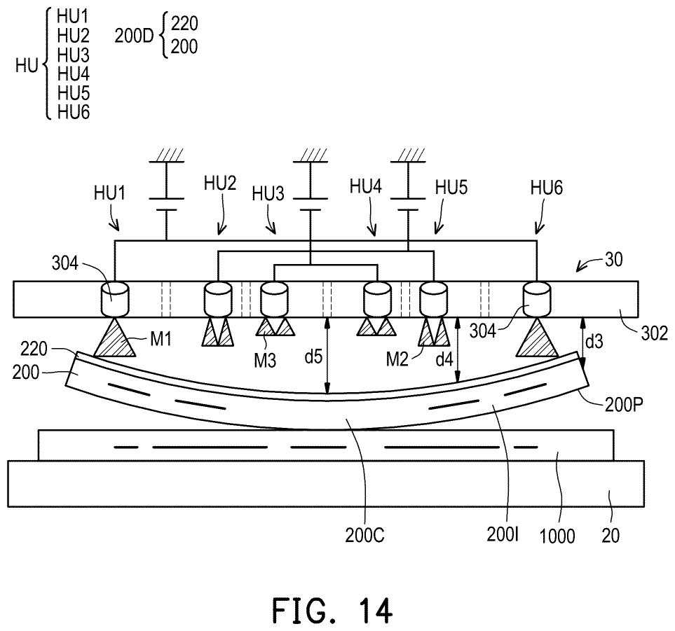

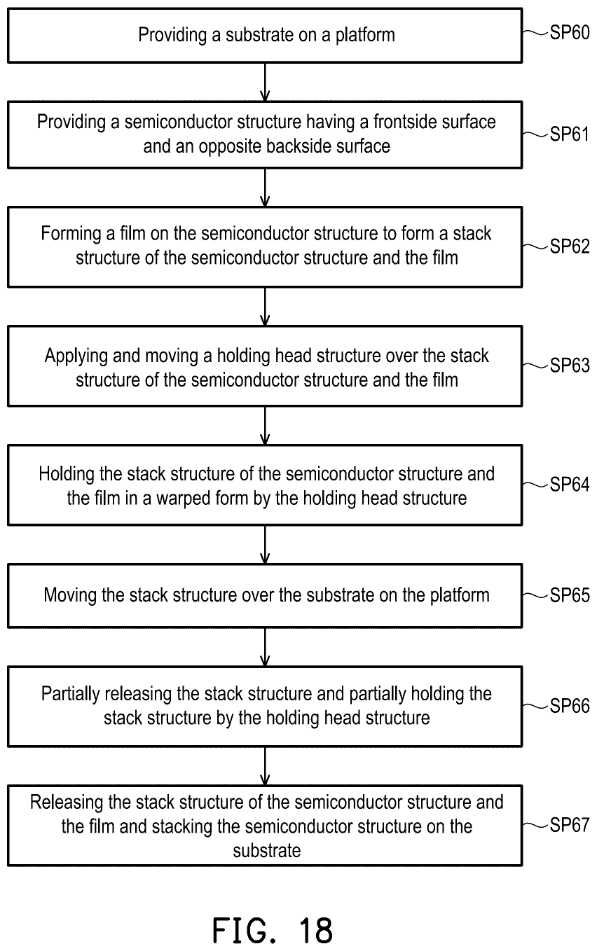

FIGS. 14-16 are schematic cross-sectional views showing various stages in a manufacturing method of a semiconductor stacked structure in accordance with some embodiments of the disclosure. FIG. 18 is a schematic process flow showing the process steps of a manufacturing method of a semiconductor stacked structure in accordance with some embodiments of the disclosure.

Referring to FIG. 14 and referring to process steps SP61 and SP62, in some other embodiments, a semiconductor structure 200 is provided with a magnetic film 220 formed thereon, and the stack structure 200D of the semiconductor structure 200 and the magnetic film 220 is held by the holding head structure 30. Herein, the elements similar to or substantially the same as the elements described above will use the same reference numbers, and certain details or descriptions of the same elements will not be repeated herein for simplification. With reference to the above paragraphs, details and descriptions illustrating certain process steps such as process steps SP60 and SP61 will be omitted as the same or similar elements and/or materials are provided and used. When the stack structure of the semiconductor structure 200 and the magnetic film 220 is held by the holding head structure 30, the backside surface 200BS of the semiconductor structure 200 is covered by the magnetic film 220 with the top surface 220TS of the magnetic film 220 facing and reacting with the holding head structure 30.

In some embodiments, the magnetic film 220 includes a magnetic material (e.g. ferromagnetic material), and the magnetic material of the magnetic film 220 includes some of the elements like iron (Fe), nickel (Ni), cobalt (Co), copper (Cu), manganese (Mn), oxides thereof, alloys, or mixtures thereof. In some embodiments, the magnetic film 220 may be formed by coating or deposition. Herein, through the magnetic film 220 attracted to the electromagnets in the holding head structure 30, the semiconductor structure 200 is held by the holding head structure 30 through magnetism, without being in physical contact with the holding head structure 30. In some embodiments, the material of the magnetic film 220 is chosen to protect the semiconductor structure 200, being easily removed in subsequent process, and satisfactorily reacted or attracted toward the electromagnets for assisting holding and carrying.

Referring to process steps SP63, SP64 and SP65, after the substrate 1000 is provided, and the stack structure 200D of the magnetic film 220 and the semiconductor structure 200 is provided, a holding head structure 30 is placed over the stack structure 200D of the semiconductor structure 200 and the magnetic film 220, and the stack structure 200D of the semiconductor structure 200 and the magnetic film 220 is held in a warped form (non-linear form) by the holding head structure 30 and moves along to the position over the substrate 1000 on the platform 20. Referring to FIG. 14, in some embodiments, the holding head structure 30 is illustrated to include holding units HU1-HU6, the operating core 304 of each holding unit is or includes at least one electromagnet, and each holding unit is independently controlled to tune the strength of the magnetic field. When the holding head structure 30 is in operation and brought close to the semiconductor structure 200, but not in touch with the semiconductor structure 200, the semiconductor structure 200 is held by the holding head structure 30 through magnetic attraction.

Through the individually controlled holding units HU (e.g. HU1-HU6) of the holding head structure 30, different voltages are applied to the holding units to adjust the strengths of the magnetic fields of the corresponding holding units, so that the holding units with various magnetic field densities can exert varying magnetic attraction (magnetic force) toward different locations of the stack structure 200D of the magnetic film 220 and the underlying semiconductor structure 200. In some embodiments, the magnetic force (magnetic attraction) may be proportionally tuned by tuning the voltages applied to the corresponding holding units.

In some embodiments, as seen in FIG. 14, with the individually controlled holding units, the holding units HU1 and HU6 are controlled to have the strongest magnetic field M1, the holding units HU2 and HU5 are controlled to have the medium magnetic field M2, and the holding units HU3 and HU4 are controlled to have the weakest magnetic field M3, so that the peripheral portion(s) 200P of the stack structure 200D is closely attached to and held toward the holding units HU1 and HU6 but the central portion 200C is most loosely held to the holding units HU3 and HU4 through different levels of attraction. Herein, as depicted in the figures, the magnetic field strength (e.g. the strength of the magnetic fields M1-M3) may be depicted as triangle(s), and the sizes of the triangles schematically relate to the scales or levels of the magnetic field strengths. That is, the strength of the magnetic field M1 is larger than that of the magnetic field M2, and the strength of the magnetic field M2 is larger than that of the magnetic field M3. As seen in FIG. 14 and in process step SP64, in some embodiments, the semiconductor structure 200 (i.e. the stack structure 200D) becomes deformed and warped into a smile shape (from the cross-sectional view). In some embodiments, the semiconductor structure 200 is deformed with the peripheral portion 200P being closely held (i.e. without being in contact with) to the holding units HU1 and HU6 with a distance d3 smaller than the distance d5 between the central portion 200C (being more distantly held) and the holding units HU3 and HU4. In some embodiments, the intermediate portion 2001 located between the peripheral portion 200P and the central portion 200C is held by and distanced from the holding units HU2 and HU5 with a distance d4 smaller than the distance d5 but larger than the distance d3.

It is understood that the sizes of these above-mentioned multiple portions of the semiconductor structure may be different, the components and/or devices included within these portions may be diverse and may be selected and designated based on the product demand and the design layout.

As seen in FIG. 14, through the magnetic reaction, the semiconductor structure 200 is firmly carried in a warped form by the holding head structure 30 to a position above and over the substrate 1000 on the platform 20, while the stack structure 200D is still spaced apart from, without physically contacting, the holding head structure 30. Referring to FIG. 14, as the semiconductor structure 200 carried by the holding head structure 30 in a warped form, the central portion 200C that is more distantly held by the holding units HU3 and HU4, the central portion 200C reaches the substrate 1000 earlier, and then direct contacts the substrate 1000.

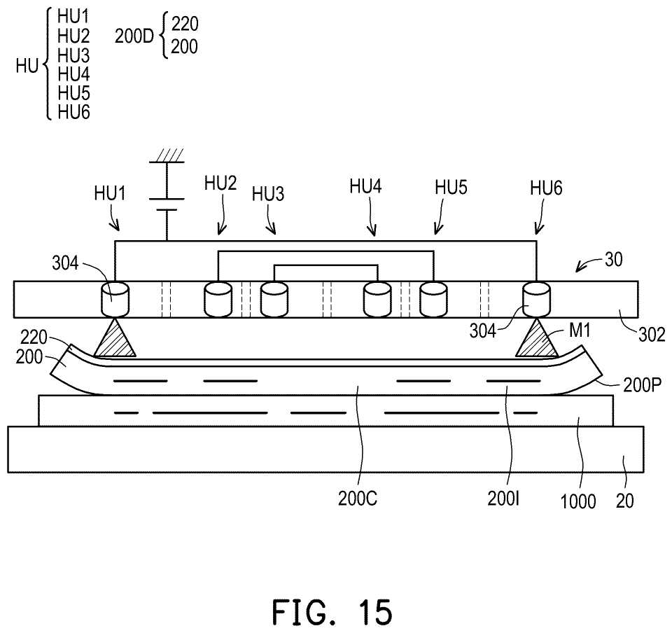

Referring to FIG. 15 and process step SP66, after the central portion 200C is in contact with the substrate 1000, the holding units HU3 and HU4 are turned off, and then the central portion 200C is released and stacked on the substrate 1000.

Referring to FIG. 15 and referring to process step SP66, following the stacking of the central portion 200C onto the substrate 1000, through the controlling unit or controller, the holding units HU2 and HU5 are switched off to release the intermediate portion 2001, so that the intermediate portion 2001 is stacked onto the substrate 1000.

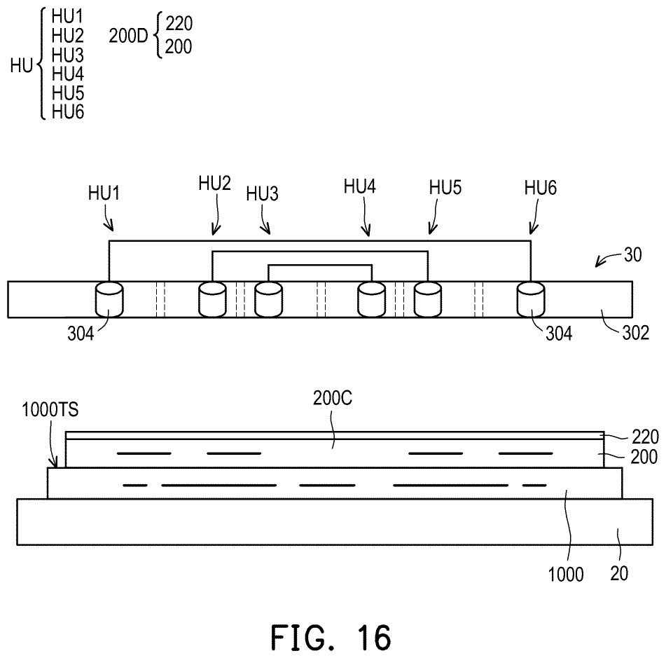

Referring to FIG. 16 and referring to process step SP67, following the stacking of the central portion 200C and the intermediate portion 2001 onto the substrate 1000, through the controller, the holding units HU1 and HU6 are switched off to release the peripheral portion 200P, so that the peripheral portion 200P is stacked onto the surface of the substrate 1000. Through sequentially controlling turning on and off the individual holding units, the corresponding portions (or locations) of the stack structure 200D may be sequentially released and stacked onto the substrate 1000. By way of individually controlling the holding units of the holding head structure, the carried structure (or object) may be released in a predetermined sequence or orders to ensure the optimal stacking, especially useful for the stacking of semiconductor structures of large sizes or multiple stacking scheme.

In the above embodiments, the semiconductor structure(s), the substrate and the stacked structures including the semiconductor structure(s) are stacked and/or bonded in a manner of a chip(s)-on-wafer (CoW) stacking and/or bonding, however the disclosure is not limited thereto. In some alternative embodiments, the semiconductor structure(s), the substrate and the stacked structures including the semiconductor structure(s) are stacked and/or bonded in a manner of a wafer-on-wafer (WoW) stacking and/or bonding.

In accordance with some embodiments, a manufacturing method for a semiconductor structure is disclosed. A substrate is provided on a platform. A semiconductor structure having a first surface and a second surface opposite to the first surface is provided. A surface charge supplying process is performed to the first surface of the semiconductor structure, and first charges are distributed over the first surface of the semiconductor structure. A holding head structure is applied over the semiconductor structure. The holding head structure includes holding units electrically isolated from one another and individually controlled, and each of the holding units includes an operating core. The semiconductor structure is held in a non-linear form by the holding head structure through electrostatic reaction, and moving the held semiconductor structure over the substrate on the platform. A first portion of the semiconductor structure is spaced apart from the first holding unit with a first distance and a second portion of the semiconductor structure is spaced apart from the second holding unit with a second distance larger than the first distance. The semiconductor structure is partially released to stack the second portion on the substrate and partially held by the holding head structure. The semiconductor structure is released and the first and second portions of the semiconductor structure are stacked on the substrate.

In accordance with some embodiments, a manufacturing method for a semiconductor structure is disclosed. A substrate is provided on a platform. A semiconductor structure is provided. A magnetic film is formed on the semiconductor structure to form a stack structure of the semiconductor structure and the magnetic film. A holding head structure is applied over the stack structure of the semiconductor structure and the magnetic film. The holding head structure includes holding units electrically isolated from one another and individually controlled, and each of the holding units includes an operating core. The stack structure of the semiconductor structure and the magnetic film is held in a non-linear form by the holding head structure through magnetic reaction, and moved over the substrate. A first portion of the stack structure is spaced apart from the first holding unit with a first distance and a second portion of the stack structure is spaced apart from the second holding unit with a second distance larger than the first distance. The semiconductor structure is partially released to stack the second portion on the substrate and partially held by the holding head structure. The semiconductor structure is released to stack the semiconductor structure on the substrate.

In accordance with some embodiments, a holding head structure is disclosed. The holding head structure includes a body of a matrix material, a plurality of operating cores embedded in the matrix material of the body, and a plurality of isolators in the body and defining holding units. The holding units are electrically isolated from one another by the plurality of isolators. Each holding unit includes at least one operating core, and each holding unit is configured to be individually controlled and be electrically connected to a power source.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A manufacturing method, comprising:
providing a substrate on a platform;
providing a semiconductor structure having a first surface and a second surface opposite to the first surface;
performing a surface charge supplying process to the first surface of the semiconductor structure, and first charges are distributed over the first surface of the semiconductor structure;
applying a holding head structure over the semiconductor structure, wherein the holding head structure includes holding units electrically isolated from one another and individually controlled, each of the holding units includes an operating core;
holding the semiconductor structure in a non-linear form by the holding head structure through electrostatic reaction, and moving the held semiconductor structure over the substrate on the platform, wherein a first portion of the semiconductor structure is spaced apart from the first holding unit with a first distance and a second portion of the semiconductor structure is spaced apart from the second holding unit with a second distance larger than the first distance;
partially releasing the semiconductor structure to stack the second portion on the substrate and partially holding the semiconductor structure to hold the first portion by the holding head structure; and
releasing the semiconductor structure to stack the first and second portions of the semiconductor structure on the substrate.

2. The manufacturing method of claim 1, wherein the holding units include a first holding unit and a second holding unit, and the operating core includes an electrode for generating charges.

3. The manufacturing method of claim 2, wherein holding the semiconductor structure in a non-linear form by the holding head structure includes operating and charging the first and second holding units individually to have second charges distributed over the first holding unit, and third charges distributed over the second holding unit, wherein a conductive type of the first charges is opposite to a conductive type of the second charges, and is the same as a conductive types of the third charges.

4. The manufacturing method of claim 3, wherein the first portion of the semiconductor structure is ring-shaped surrounding the second portion, and the first portion is held by the first holding unit through electrostatic attraction.

5. The manufacturing method of claim 3, wherein after moving the held semiconductor structure over the substrate, partially releasing the semiconductor structure includes operating and charging the second holding unit to have the third charges distributed over the second holding unit so that the second portion of the semiconductor structure is repelled and stacked onto the substrate.

6. The manufacturing method of claim 5, wherein releasing the semiconductor structure to stack the first and second portions of the semiconductor structure on the substrate includes operating and charging the first holding unit to have the third charges distributed over the first holding unit so that the first portion of the semiconductor structure is repelled and stacked onto the substrate.

7. The manufacturing method of claim 1, further comprising bonding the semiconductor structure stacked on the substrate with the substrate to electrically connecting the semiconductor structure and the substrate.

8. The manufacturing method of claim 1, further comprising forming a chargeable film on the semiconductor structure before performing a surface charge supplying process, and the surface charge supplying process is performing to the chargeable film so that the first charges are distributed over a surface of the chargeable film.

9. A manufacturing method, comprising:
providing a substrate on a platform;
providing a semiconductor structure;
forming a magnetic film on the semiconductor structure to form a stack structure of the semiconductor structure and the magnetic film;
applying a holding head structure over the stack structure of the semiconductor structure and the magnetic film, wherein the holding head structure includes holding units electrically isolated from one another and individually controlled, each of the holding units includes an operating core;
holding the stack structure of the semiconductor structure and the magnetic film in a non-linear form by the holding head structure through magnetic reaction, and moving the held semiconductor structure over the substrate, wherein a first portion of the stack structure is spaced apart from the first holding unit with a first distance and a second portion of the stack structure is spaced apart from the second holding unit with a second distance larger than the first distance;
partially releasing the semiconductor structure to stack the second portion on the substrate and partially holding the semiconductor structure to hold the first portion by the holding head structure; and
releasing the semiconductor structure to stack the semiconductor structure on the substrate.

10. The manufacturing method of claim 9, wherein the holding units include a first holding unit and a second holding unit, and the operating core includes an electromagnet for exerting magnetic fields.

11. The manufacturing method of claim 10, wherein holding the semiconductor structure in a non-linear form by the holding head structure includes operating the first and second holding units individually, and the first holding unit exerts a first magnetic field, the second holding unit exerts a second magnetic field smaller than the first magnetic field.

12. The manufacturing method of claim 10, wherein the first portion of the semiconductor structure is ring-shaped surrounding the second portion, and the first portion is held by the first holding unit through magnetic attraction, and the second portion is held by the second holding unit through magnetic attraction.

13. The manufacturing method of claim 10, wherein after moving the held semiconductor structure over the substrate, partially releasing the semiconductor structure includes turning off the second holding unit to release the second portion onto the substrate.

14. The manufacturing method of claim 13, wherein releasing the semiconductor structure to stack the semiconductor structure on the substrate includes turning off the first holding unit to release the first portion.

15. The manufacturing method of claim 10, wherein the holding units further include a third unit, and holding the semiconductor structure in a non-linear form further includes operating the third holding unit to exert a third magnetic field, wherein the third magnetic field is smaller than the first magnetic field and larger than the second magnetic field.

16. The manufacturing method of claim 15, wherein the stack structure further includes a third portion correspondingly held by the third holding unit and spaced apart from the third holding unit with a third distance, the third distance is larger than the first distance and smaller than the second distance.

17. The manufacturing method of claim 9, further comprising bonding the semiconductor structure stacked on the substrate with the substrate to electrically connecting the semiconductor structure and the substrate.

18. A structure, comprising:
a body of a matrix material;
a plurality of operating cores embedded in the matrix material of the body;
a plurality of isolators in the body and defining holding units, wherein the holding units are electrically isolated from one another by the plurality of isolators, and each holding unit includes at least one operating core, and each holding unit is configured to be individually controlled and be electrically connected to a power source.

19. The structure of claim 18, wherein the at least one operating core includes an electrode.

20. The structure of claim 18, wherein the at least one operating core includes an electromagnet.
